(19) United States
(12) Patent Application Publication
(10) Pub. No.: US 2024/0102167 A1
(43) Pub. Date: Mar. 28, 2024

(54) NOVEL COATING METHOD OF COMPLEX 3D STRUCTURES USING LOW PRESSURE CHEMICAL VAPOR DEPOSITION

(71) Applicant: California Institute of Technology, Pasadena, CA (US)

(72) Inventors: Matthew R. Dickie, Altadena, CA (US); Su C. Chi, Pasadena, CA (US); Billy Chun-Yip Li, Pasadena, CA (US); William C. West, South Pasadena, CA (US); Harold Frank Greer, Los Angeles, CA (US)

(73) Assignee: California Institute of Technology, Pasadena, CA (US)

(21) Appl. No.: 18/476,808

(22) Filed: Sep. 28, 2023

Related U.S. Application Data
(60) Provisional application No. 63/410,918, filed on Sep. 28, 2022.

(51) Int. Cl. C23C 16/458; C23C 16/34

(52) U.S. Cl. CPC C23C 16/4587; C23C 16/345; C23C 16/4583

(57) ABSTRACT

A boat used in a chemical vapor deposition (CVD) furnace is configured to hold one or more complex three-dimensional (3D) structures when performing a coating. A platform wafer is placed horizontally in the boat to support the complex 3D structures and a mount is positioned to secure the complex 3D structures on the platform wafer during the CVD process. One or more “witness” wafers may also be placed in the boat for analyzing the thin-film coating. The platform wafer may be positioned between or bracketed by the vertical wafers. Parts with coatings manufactured using LPCVD are further disclosed.

### CROSS REFERENCE TO RELATED APPLICATION(S)

This application claims the benefit under 35 U.S.C. Section 119(e) of the following co-pending and commonly-assigned application(s):
U.S. Provisional Application Ser. No. 63/410,918, filed on Sep. 28, 2022, by Matthew R. Dickie, Su C. Chi, Billy Chun-Yip Li, William C. West and Harold Frank Greer, entitled “NOVEL COATING METHOD OF COMPLEX 3D STRUCTURES USING LOW PRESSURE CHEMICAL VAPOR DEPOSITION,” docket number CIT 8884-P;
which application(s) is/are incorporated by reference herein.

### STATEMENT REGARDING FEDERALLY SPONSORED RESEARCH AND DEVELOPMENT

This invention was made with government support under Grant No. 80NMO0018D0004 awarded by NASA (JPL). The government has certain rights in the invention.

### BACKGROUND OF THE INVENTION

### 1. Field of the Invention

This invention relates to a novel coating method of three-dimensional (3D) structures using chemical vapor deposition, and a resulting manufacture.

### 2. Description of the Related Art

There is a need in the art to perform a thin-film coating process on complex 3D structures that do not conform to the shapes and configurations of objects normally processed by standard thin-film coating systems. The present disclosure satisfies this need.

### SUMMARY OF THE INVENTION

The present disclosure reports on a method and system for coating three dimensional structures using chemical vapor deposition (CVD) by configuring a boat with a platform (e.g., wafer) placed horizontally in the boat to support the complex 3D structures during the CVD. Witness wafers may optionally be placed vertically in slots of the boat so that the platform wafer is between the witness wafers. The system further includes a mount for securely for holding the 3D structures on the platform during the CVD process. In one embodiment, the boat is for a low pressure chemical vapor deposition (LPCVD) furnace intended to only coat wafers.

Example embodiments include, but are not limited to, the following.
1. A method, comprising:
configuring a boat to hold one or more three-dimensional (3D) structures, wherein a platform wafer is placed horizontally in the boat to support the complex 3D structures;
loading the boat, the 3D structures, and the platform wafer, into a chemical vapor deposition (CVD) furnace;
performing a coating of the 3D structures supported on the platform wafer in the CVD furnace; and
unloading the 3D structures from the CVD furnace after the coating is performed.
2. The method of embodiment 1, wherein the boat comprises a first slot and a second slot and the configuring comprises placing a first wafer vertically in the first slot; placing a second wafer vertically in the second slot; and placing the platform wafer horizontally between the first wafer and the second wafer.
3. The method of embodiment 1 or 2, further comprising placing the 3D structures on the platform wafer using one or more rings to keep the 3D structures from moving after being placed on the on the platform wafer.
4. The method of any of the embodiments 1-3, wherein the coating is a silicon nitride coating.
5. The method of any of the embodiments 1-4, wherein the CVD furnace is a CVD furnace intended to only coat wafers.
6. The method of any of the embodiments 1-5, wherein the CVD furnace is a low-pressure CVD furnace and the coating is performed at a pressure in a range of 10 mTorr to below 1 Torr (e.g., 10 mTorr to 500 mTorr inclusive of end points).
7. The method of any of the embodiments 1-6, further comprising analyzing the coating on at least one of the 3D structures or one or more witness wafers loaded into the boat with the 3D structures.
8. One or more three-dimensional (3D) structures coated by the method of any of the embodiments 1-7.
10. The structures of embodiment 8 comprising or consisting essentially of silicon and germanium and the coating.
11. The structures of embodiment 9, comprising a platform connected to columns extending from the platform.
12. The structures of embodiment 9, comprising a component of a radioisotope thermoelectric generator (RTGs), e.g., a thermoelectric module comprising a couple comprising a heat receptor, a n-type thermoelectric material, and a p-type thermoelectric material.
13. An apparatus, comprising:
a boat, comprising:
a horizontal platform; and
a mount for securely for holding a three dimensional part other than a wafer on the platform during a low pressure chemical vapor deposition process.
14. The apparatus of embodiment 13, wherein the mount comprises fixture fixing the part on a top surface of the horizontal platform.
15. The apparatus of embodiment 13 or 14, further comprising a first vertical sidewall and a second vertical sidewall positioned, wherein the platform is between the sidewalls.
16. The apparatus of embodiment 15, wherein the sidewalls comprise witness wafers used to characterize a coating deposited using the chemical vapor deposition process.
17. An article of manufacture or part or device, comprising:
a three dimensional (3D) part different from a wafer and comprising a top surface; a bottom surface; and vertical sidewalls; and
a coating on each of the surfaces characterized by being deposited by low pressure chemical vapor deposition.
18. The article of manufacture of embodiment 17, wherein:
the 3D part comprises or consists essentially of a semiconductor or a ceramic; and
the coating comprises or consists essentially of at least one of silicon, an oxide of silicon, a nitride of silicon, an oxynitride of silicon, or a doped version thereof;
the coating has at least one of:
a uniform thickness across one or more of the surface to within 60% of the average thickness, or
the coating has a tensile stress in a range of 50 MPa-150 MPa.
19. The article of manufacture of embodiment 17 or 18, wherein the part comprises a radioisotope thermoelectric generator (RTGs), a ceramic part; one or more couples in a thermoelectric module; a 3D printed part, a porous 3D printed part; a battery component; a mirror; or a semiconductor device.
20. The article of manufacture, part, or device of any of the embodiments 17-19 manufactured using the method of any of the embodiments 1-7.
21. The method or device of any of the embodiments 1-20 using the apparatus of any of the embodiments 13-16.
22. The method of any of the embodiments 1-7 wherein the boat comprises the apparatus of any of the embodiments 13-16.

### BRIEF DESCRIPTION OF THE DRAWINGS

Referring now to the drawings in which like reference numbers represent corresponding parts throughout:

FIG. 1 is a flowchart that illustrates the steps for a novel coating method of complex 3D structures using LPCVD, and a resulting manufacture.

FIGS. 2, 3, 4 and 5 illustrate the components involved in the novel coating method of FIG. 1.

FIG. 6. Schematic of a LPCVD furnace including a boat, part and witness wafers according to embodiments of the present invention.

FIG. 7A illustrates the part and FIGS. 7B-7Z and FIGS. 8A-8K illustrate characterization of the coating at the various locations 1-10 indicated in FIG. 7A, wherein FIGS. 7B and 7C illustrate the coating thickness at location 1 by scanning electron microscope and in tabular form, respectively, FIGS. 7D and 7E illustrate elemental mapping of the elements indicated at location 1, FIGS. 7F and 7G illustrate the coating thickness at location 2 by scanning electron microscope and in tabular form, respectively, FIGS. 7H and 7I illustrate elemental mapping of the elements indicated at location 2, FIGS. 7J and 7K illustrate the coating thickness at location 4 by scanning electron microscope and in tabular form, respectively, FIGS. 7L and 7M illustrate elemental mapping of the elements indicated at location 4, FIGS. 7N and 7O illustrate the coating thickness at location 5 by scanning electron microscope and in tabular form, respectively, FIGS. 7P and 7Q illustrate elemental mapping of the elements indicated at location 5, FIGS. 7R and 7S illustrate the coating thickness at location 6 by scanning electron microscope and in tabular form, respectively, FIGS. 7T and 7U illustrate elemental mapping of the elements indicated at location 6, FIGS. 7V and 7W illustrate the coating thickness at location 7 by scanning electron microscope and in tabular form, respectively, FIGS. 7X and 7Y illustrate elemental mapping of the elements indicated at location 7, FIGS. 7Z and 8A illustrate the coating thickness at location 8 by scanning electron microscope and in tabular form, respectively, FIGS. 8B and 8C illustrate elemental mapping of the elements indicated at location 8, FIGS. 8D and 8E illustrate the coating thickness at location 9 by scanning electron microscope and in tabular form, respectively, FIGS. 8F and 8G illustrate elemental mapping of the elements indicated at location 9, FIGS. 8H and 8I illustrate the coating thickness at location 10 by scanning electron microscope and in tabular form, respectively, FIGS. 8J and 8K illustrate elemental mapping of the elements indicated at location 10, and FIG. 8L is a summary tabulating the thicknesses, wherein the elemental mapping confirms the Si3N4 coating and the scale in the elemental mapping images is 10 micrometers, 1 is SiMo hot shoe (Si3N4 confirmed on hot shoe), 2 is SiMo hot shoe (Si3N4 confirmed on surface), 4, 9 is n pellet inner surface (Si3N4 confirmed on surface), 5, 10 is p-pellet inner surface, Si3N4 confirmed on surface), 6 is p pellet outer surface (Si3N4 confirmed on surface), 7 and 8 is SiMo hot shoe inner surface (Si3N4 confirmed on surface). SEM was used to measure thickness of coating and elemental mapping of Si3N4 on the surface of the hot shoe, p-pellet, and n-pellet.

FIG. 9 illustrates chemical cleaning and the setup before and after coating.

FIG. 10 illustrates the deposition conditions of the LPCVD used to obtain the data presented herein.

FIG. 11 illustrates the weight gain of SiN versus coating time of SiN which can be used to determine thickness of the coating.

FIG. 12 is a schematic of a part having a coating of thickness T deposited according to embodiments described herein.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

A motivation for the method and apparatus described herein included the need to recreate a legacy thin-film coating process used by NASA, circa 1970, to passivate silicon germanium (SiGe) components of radioisotope thermoelectric generators (RTGs) using silicon nitride. The problem was the original coating systems used no longer existed. The inventors investigated current coating options available, and. after reviewing the silicon nitride thin film deposition options available, decided to coat the SiGe parts using a low pressure chemical vapor deposition (LPCVD) furnace. One of the goals of the project was to develop a silicon nitride passivation coating equivalent or superior to one used in the past, but using current coating technology.

The challenge with using the LPCVD furnace is that it is designed to coat standard semiconductor wafers, which are essentially planar objects. The SiGe RTG components are complex 3D structures consisting of a square platform with two square columned tower-like structures rising from the middle. The parts were dimensionally compatible to fit in the LPCVD furnace.

Technical Description

### First Embodiment: Method

The present invention discloses a method to use a chemical vapor deposition (in this example, LPCVD furnace) to coat complex 3D structures. In this illustrative example, the LPCVD systems are quartz tube furnaces intended to only coat wafers. Thus, a conventional semiconductor LPCVD furnace system is used in a novel manner and a method to safely and securely load the complex 3D structures into the LPCVD furnace was developed to use MDL's standard low-stress silicon nitride process to coat the parts. However, other CVD or LPCVD systems could be used.

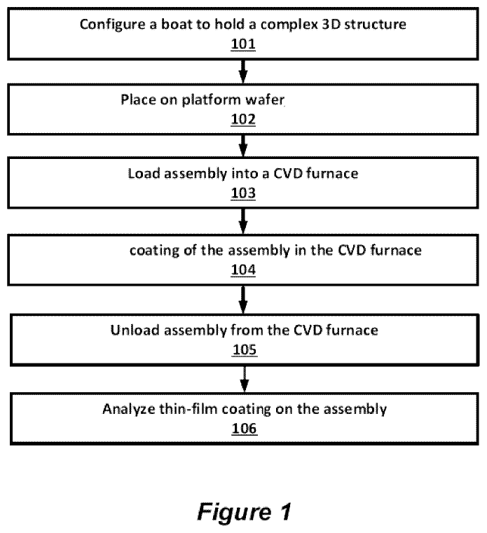

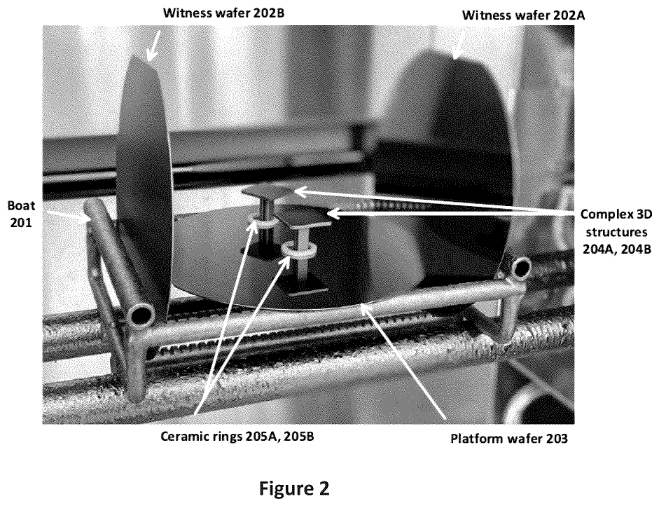

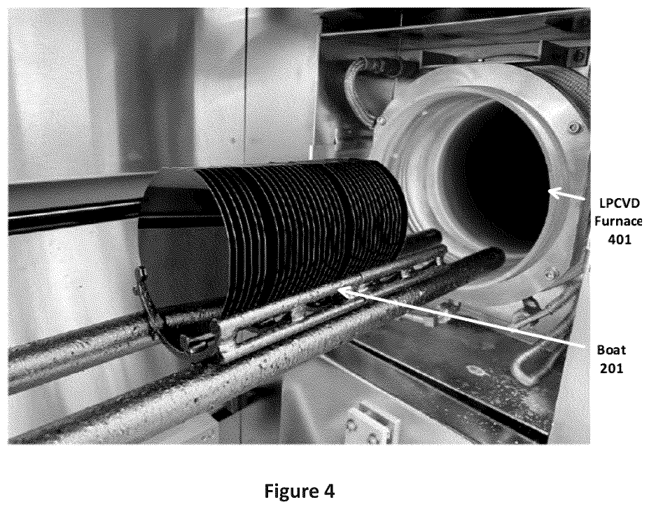

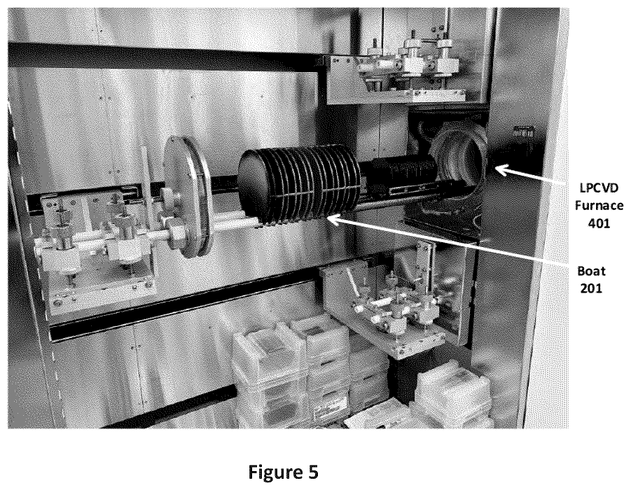

FIG. 1 is a flowchart that illustrates the steps for a novel coating method of (e.g., complex) 3D structures using CVD (e.g., LPCVD) and a resulting manufacture. FIGS. 2, 3, 4 and 5 illustrate the components used in this method.

Block 101 represents the step of configuring a boat to hold one or more 3D structures, which in one embodiment comprises SiGe RTG components, although other embodiments may comprise other complex 3D structures.

In one embodiment, illustrated in FIG. 2, a 150 mm wafer boat 201 is used, with one 150 mm standard silicon wafer conventionally placed vertically in a first slot of the boat 201 as a (e.g., witness) wafer 202A, one 150 mm standard silicon wafer conventionally placed vertically in a last slot of the boat 201 as a (e.g., witness) wafer 202B, and one 150 mm standard silicon wafer unconventionally placed horizontally in the boat 201 as a platform wafer 203 to support the complex 3D structures 204A, 204B, wherein the platform wafer 203 is bracketed or positioned between the wafers 202A, 202B in the (e.g., first) and (e.g., last) slots of the boat 201. In other embodiments, the wafers 202A, 202B may be placed in other slots of the boat 201, or may be omitted from the boat 201, either selectively or entirely. The witness wafers can be used to measure the variation in the properties (e.g., thickness or tensile stress) of the coating across the part, as distance from the gas source of the LPCVD is increased (the first wafer 202A is closest to the gas source, the second wafer 202B is furthest; in one or more embodiments, the properties of the coating on the part are between the properties measured on the first wafer 202A and the properties measured on the second wafer 202B).

More generally, FIG. 2 illustrates the boat comprises a horizontal platform; and a mount for securely for holding a three dimensional part on the platform during a chemical vapor deposition process. In the embodiment shown, the mount comprises an opening dimensioned to frictionally grasp the part and a weight that secures the part on a top surface of the horizontal platform. In other embodiments, the mount comprises a fixture that fixes or secures the part on the platform. In yet another embodiment, the platform comprises etched (e.g.; shallow) wells and the part (structures) stand in the wells (i.e.; the mount comprises the wells).

Block 102 represents the step of placing the complex 3D structures 204A, 20B on the platform wafer 203, using a mounting piece (in this example, ceramic rings 205A, 205B) to keep the complex 3D structures 204A, 204B from moving after being placed on the on the platform wafer 203.

Block 103 represents the step of loading an assembly into the CVD reactor (e.g., LPCVD furnace) 401, wherein the assembly is comprised of the boat 201, the wafer 202A, the wafer 202B, the platform wafer 203, the complex 3D structures 204A, 204B, and the mounting piece 205A, 205B.

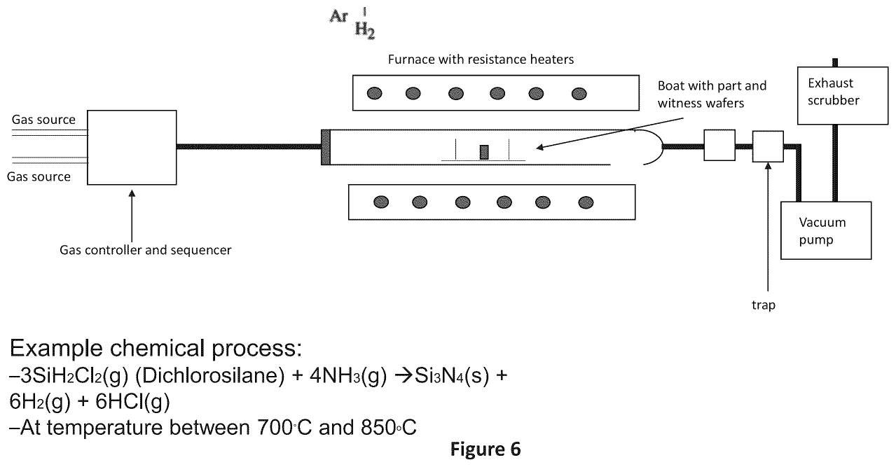

Block 104 represents the step of performing a (e.g., thin-film) coating of at least the 3D structure or the entire assembly in the CVD (e.g., LPCVD furnace) 401. In one embodiment, a standard LPCVD silicon nitride coating recipe is used. In one embodiment, illustrated in FIG. 6, a LPCVD furnace comprises a tube in which the boat holding the 3D structure is placed and that is subsequently evacuated to low pressures below atmospheric pressure, e.g., 10 mTorr to 1 Torr, 10 mTorr-120 mTorr, less than 500 mTorr, less than 700 mTorr, or less than 350 mTorr. The tube under low pressure is then heated up to deposition temperature (e.g., the temperature at which the precursor gas decomposes). Example deposition temperatures include, but are not limited to, 700-900° C. (e.g., 835° C.), 425-900° C., or 700-900° C. depending on the process and the reactive gases being used (typically DCS, NH₃, NH₂Cl and H₂ for SiN deposition). Precursor Gas is introduced into the tube so that it diffuses and reacts with the surface of the 3D structure creating the solid phase material. Any excess gas is then pumped out of the tube.

An example of the LPCVD reactor is shown in FIG. 6. Another example of an LPCVD reactor that can be used is shown in FIG. 1 of Ivanda, M., et al. “Low pressure chemical vapor deposition of different Silicon nanostructures.” International Journal of Thermophysics 57 (2009): 1-5, which reference is incorporated by reference herein.

Block 105 represents the step of unloading the 3D structure/assembly from the CVD reactor (e.g., LPCVD furnace) 401, after the coating is performed.

Block 106 represents the step of optionally analyzing the (e.g., thin-film) coating of the assembly, after the assembly has been unloaded from the CVD reactor (LPCVD furnace) 401. In this regard, the coating of the complex 3D structures 204A, 204B, as well as the witness wafers 202A, 202B, may be analyzed to measure the film's thickness and stress.

### Second Embodiment: Parts that can be Coated

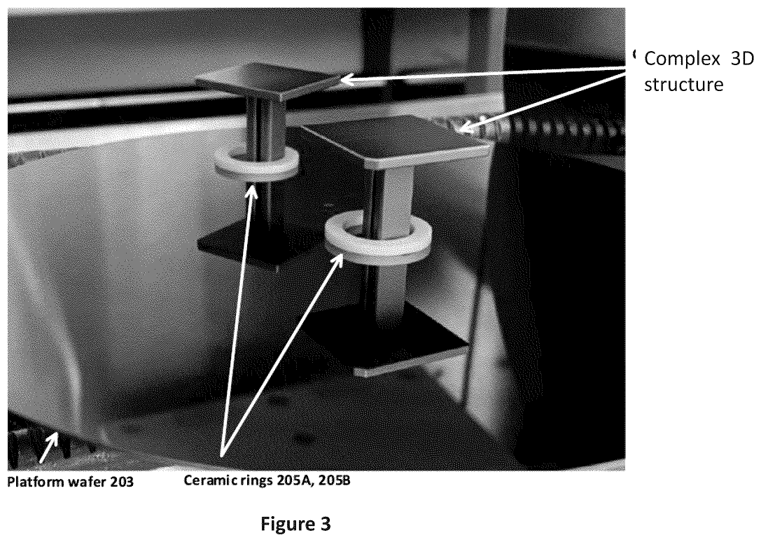

FIG. 3 illustrates an article of manufacture that can be coated using the methods described herein. The three dimensional part comprises a 3D non-wafer part/structure comprising a semiconductor or ceramic), e.g., high aspect ratio, e.g., comprising a horizontal surface and a vertical surface at least half as long as the horizontal surface. The coating comprising or consisting essentially of at least one of a polysilicon, silicon nitride, silicon oxynitride, or silicon dioxide. The coating has a uniform thickness on all exposed surfaces of the part, to within 1%. In one example, the part comprises a component of radioisotope thermoelectric generator (RTGs).

### Working Examples

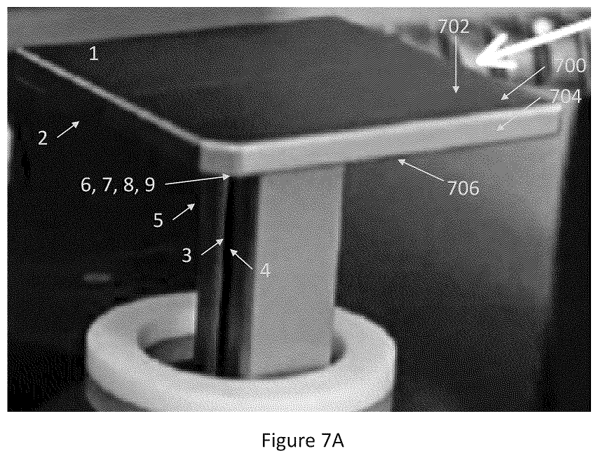

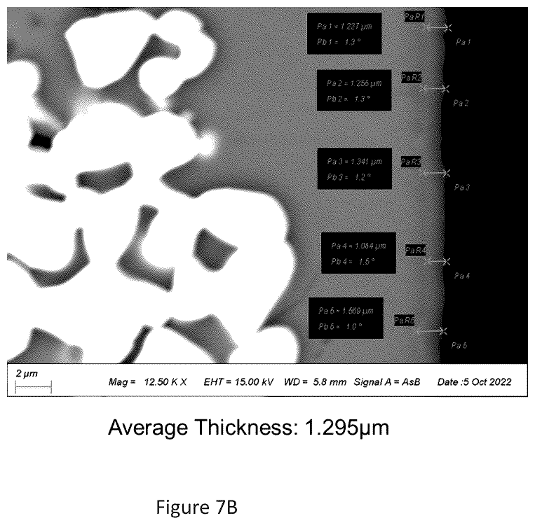

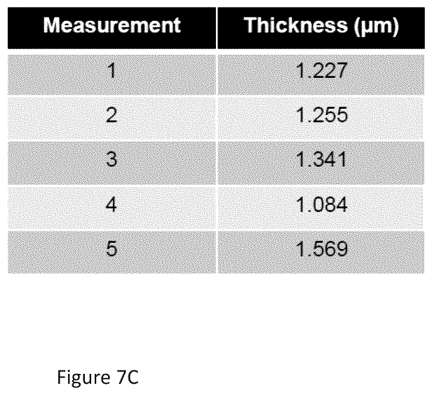

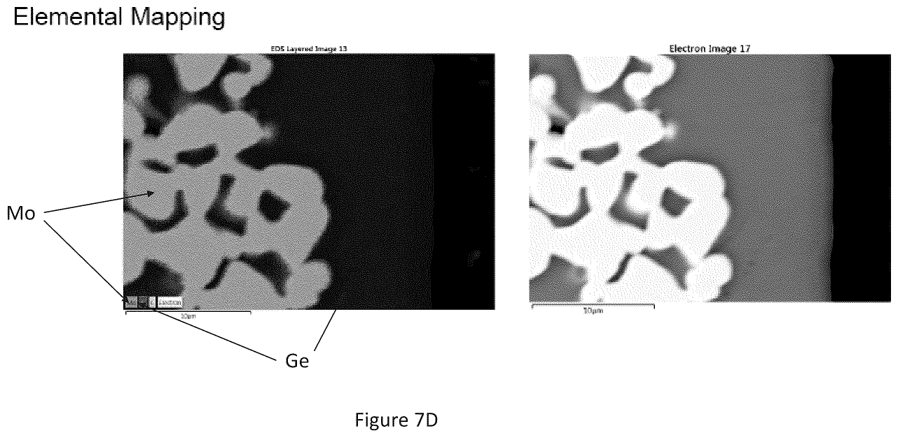

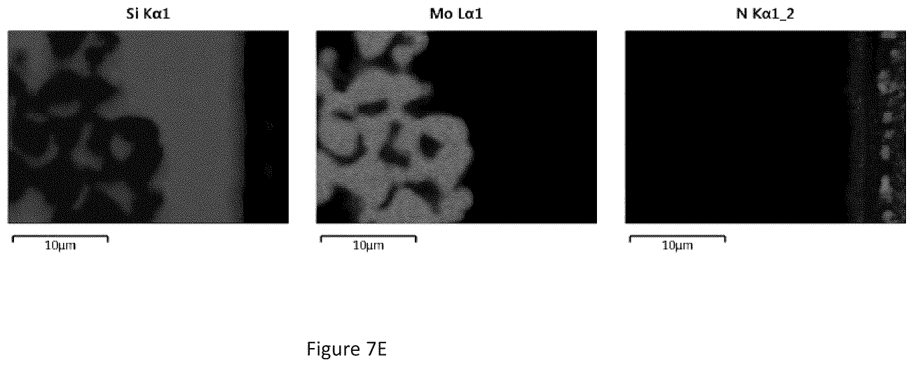

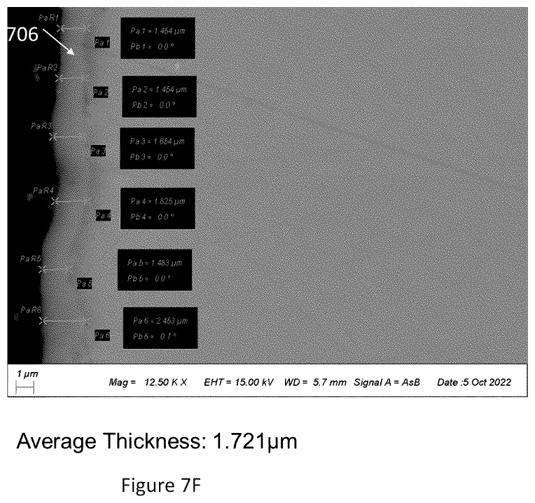

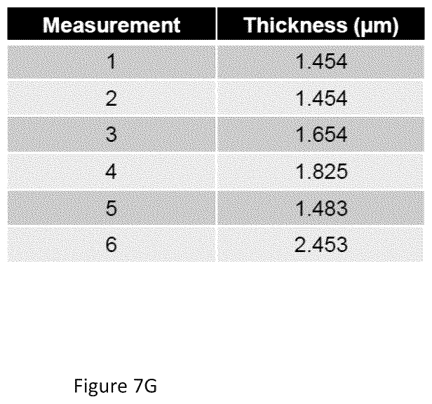

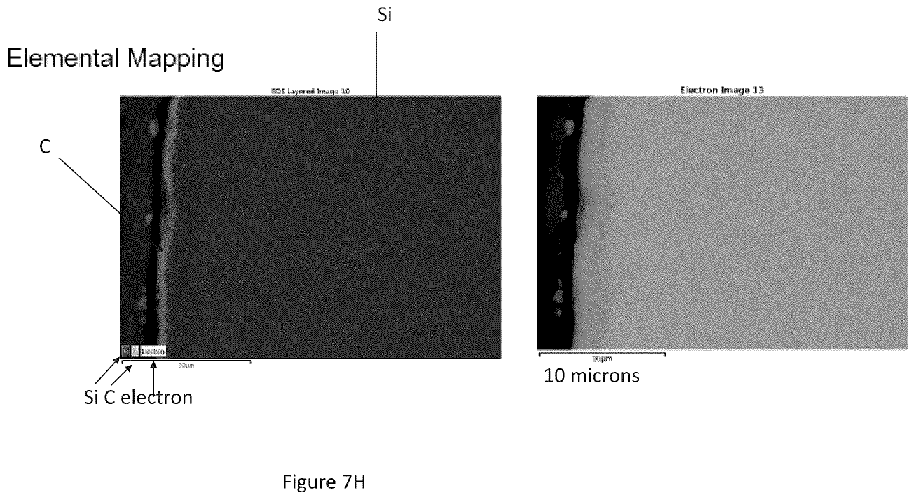

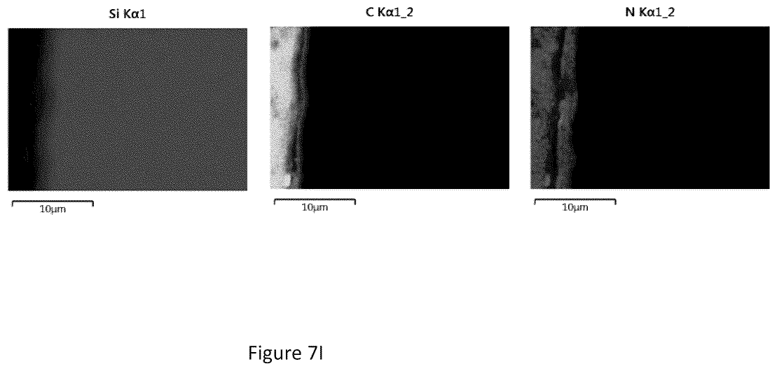

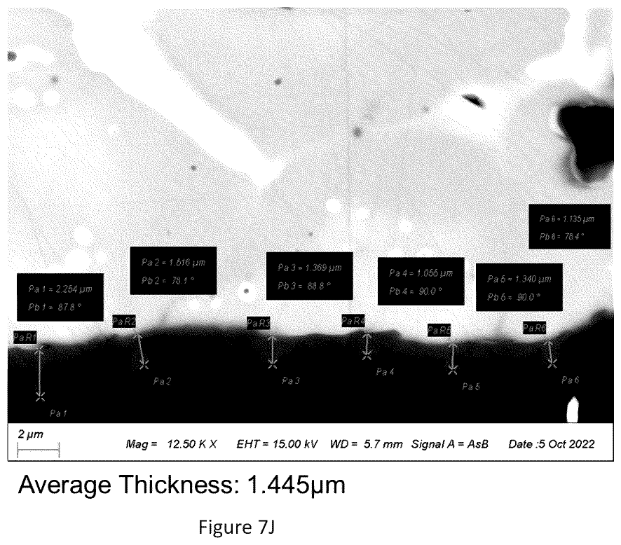

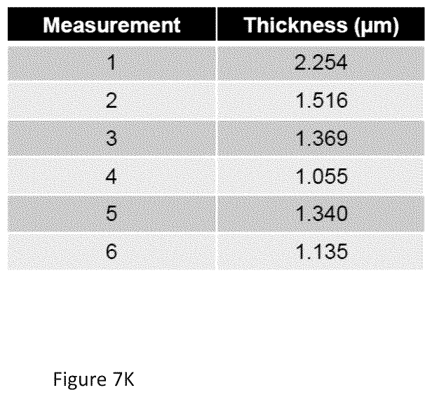

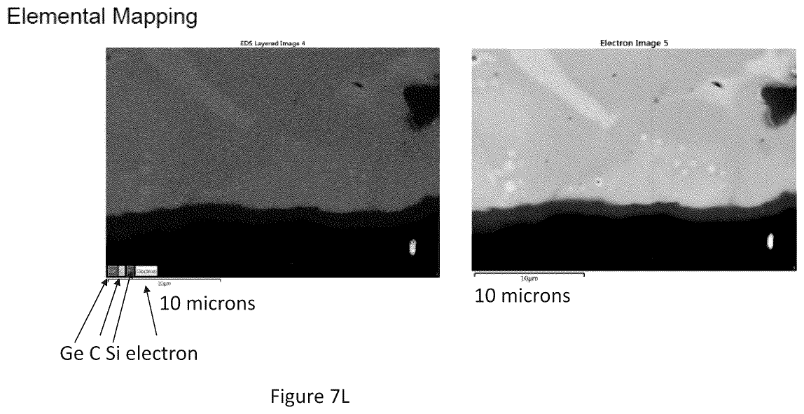

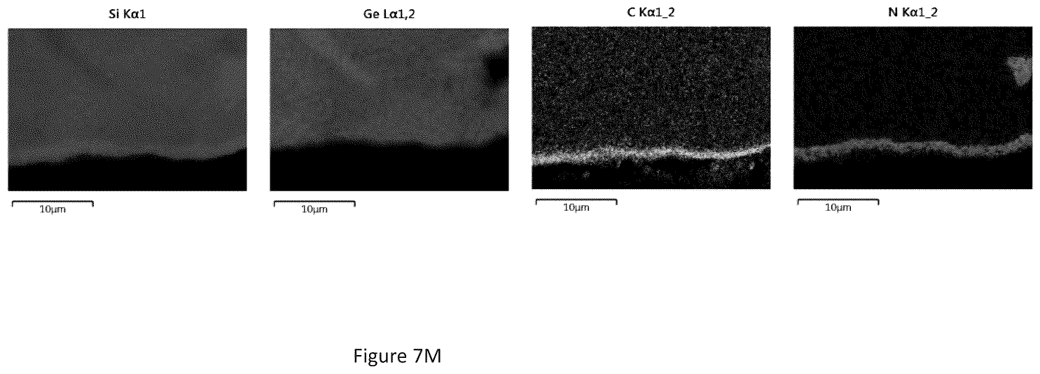

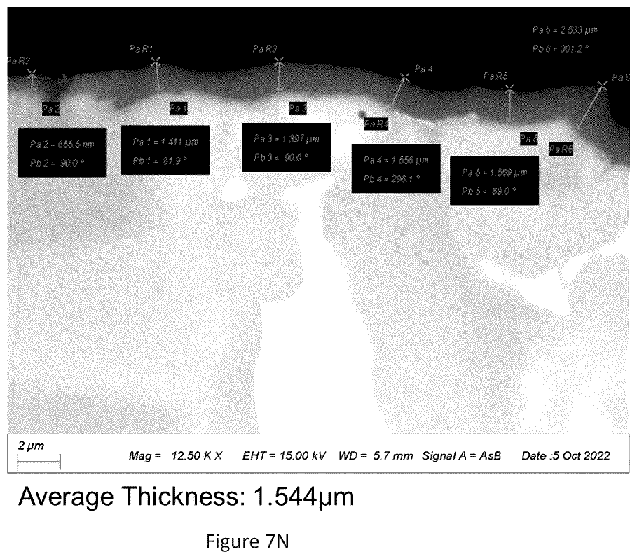

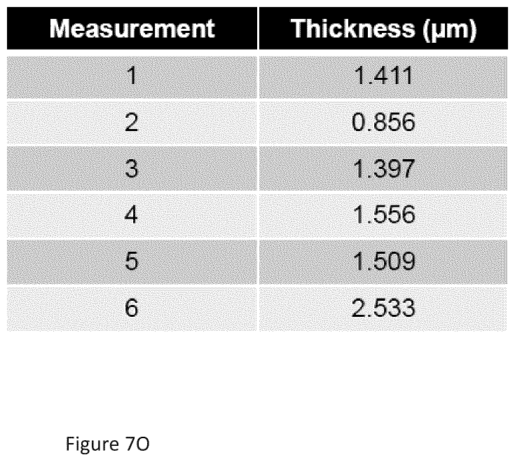

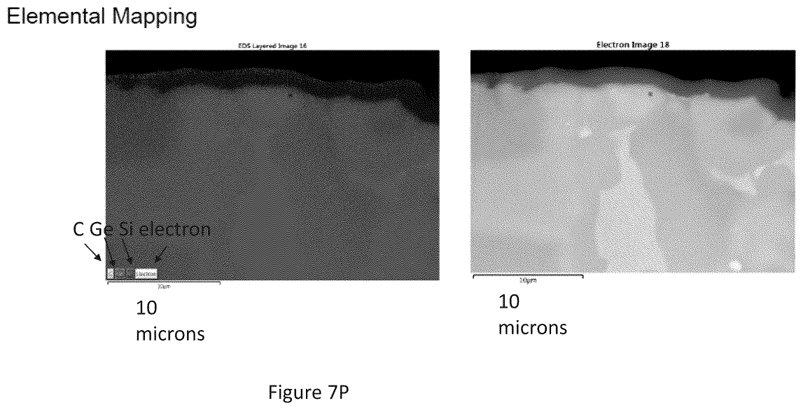

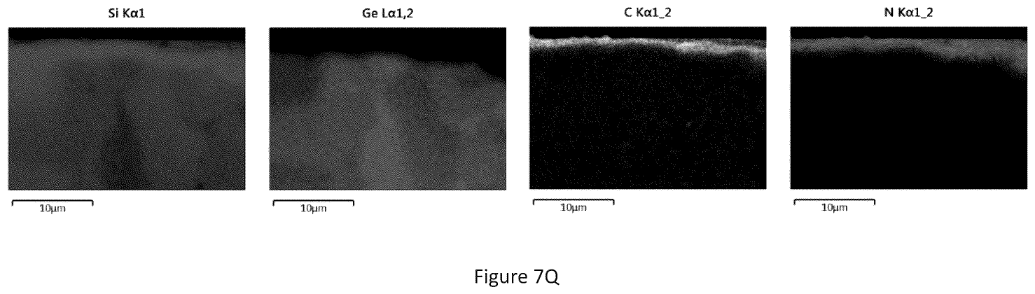

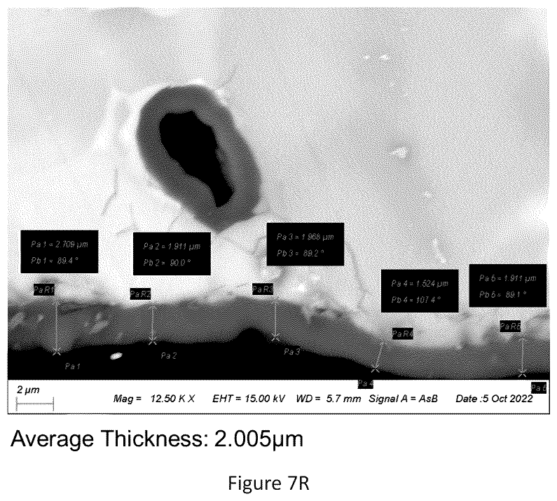

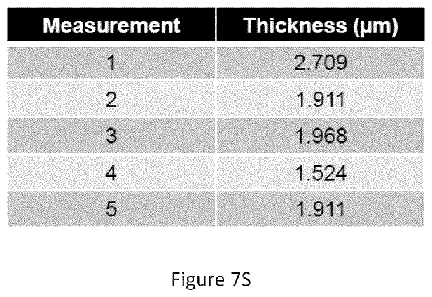

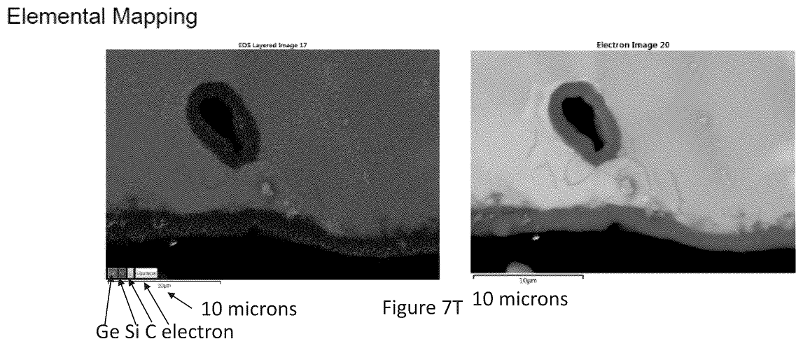

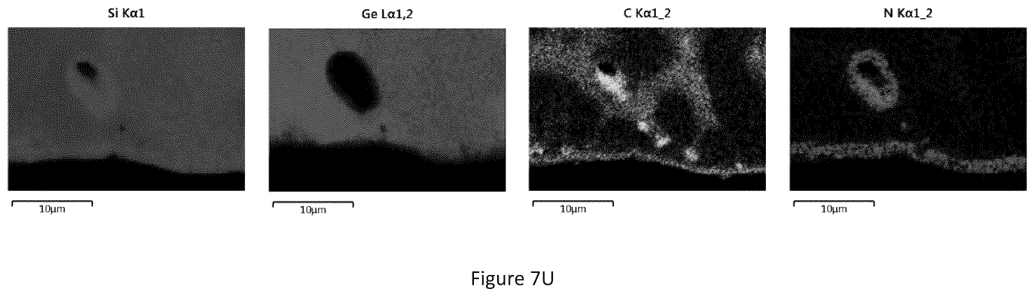

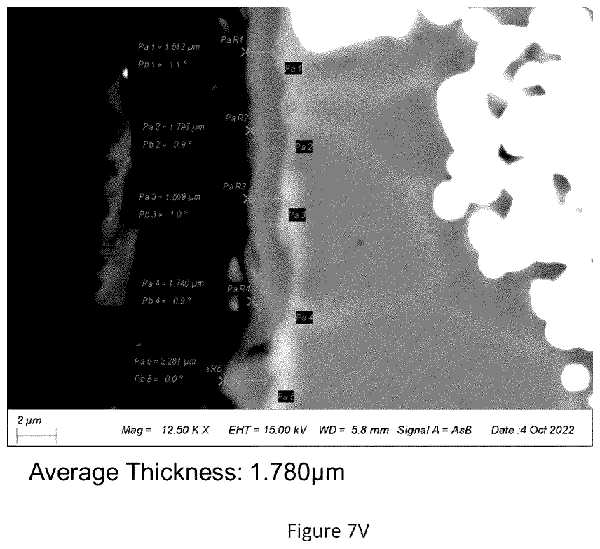

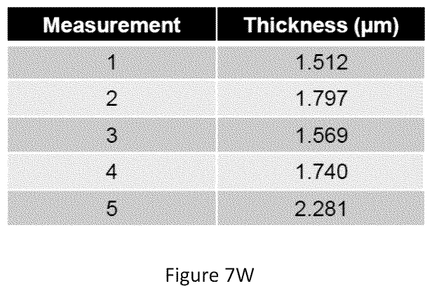

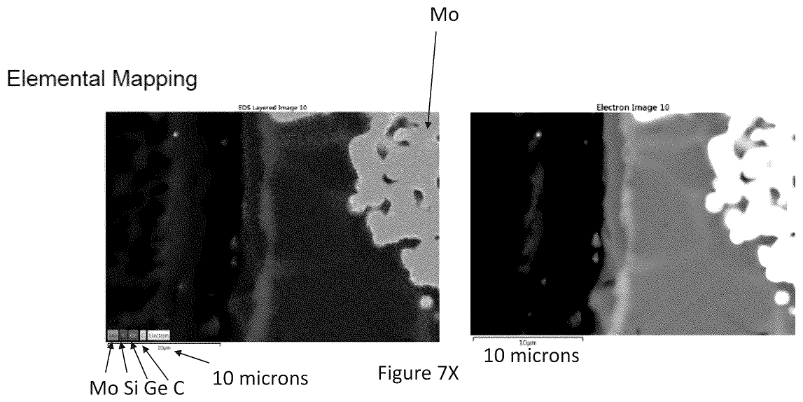

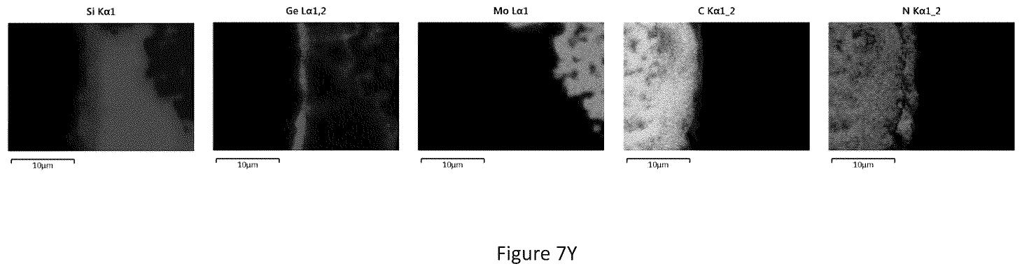

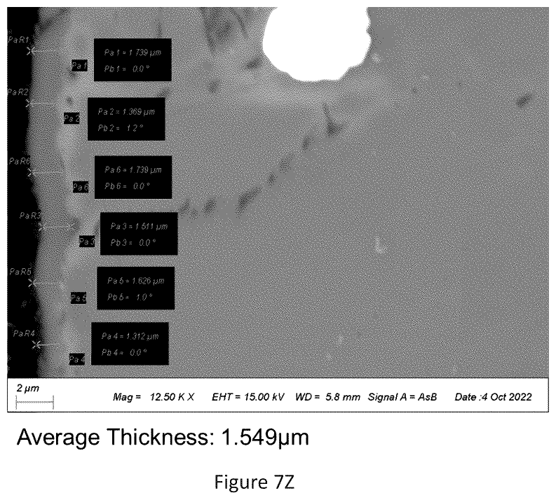

FIGS. 7A-8L illustrate a three dimensional part 700 (an RTG part or thermoelectric couple) comprising a top surface 702; a bottom surface 704 on an underside opposite the top surface; and vertical sidewalls 704; and a coating 706 on each of the surfaces characterized by being deposited by low pressure chemical vapor deposition as described herein (the furnace of FIG. 6 at a pressure of 120 mTorr and a deposition temperature of 835° C.) For the data in FIGS. 7B-8L, the coating is a Si₃N₄ coating with a thickness at the different locations on the part having an average of 1.531 μm with a standard deviation of 0.41 μm. The deposition rate of the coating was 30 Angstroms per minute. In the embodiment shown the thermoelectric module comprises a couple comprising a hot shoe or heat receptor, p-type thermoelectric alloy or material (e.g., p-pellet) and an n-type thermoelectric alloy or material (n-pellet).

By measuring the thickness of the coating on the two vertical witness wafers, the range of coating properties across the part can be measured (e.g., maximum and minimum film thickness and film tensile stress). The range in coating properties is due the varying distance of locations on the part from the precursor gas source of the LPCVD reactor. The maximum and minimum is determined from the measurement of the witness wafer closest to the gas source and furthest from the gas source, respectively. In one example, a 1 micron thickness coating on the part was measured to have a variation of 600 angstroms across a horizontal distance corresponding to the diameter of a 150 mm wafer. In another example, the variation is such that the first witness water 202A has a coating thickness of 1.55 microns, the second witness wafer 202B has a coating thickness of 1.45 microns, when the first and second witness wafers are separated by a horizontal distance of 150 mm. The coating films deposited using the methods described herein (including the films illustrated in FIGS. 7A-8L were measured to have a tensile stress in a range of 50 Megapascals (MPa) to 150 MPa using a contactless technique (the 128 series Opti-Lever dual laser auto-switching technology featuring a micropositioning detector to measure the laser beam deflection with high precision over a large dynamic range of small to large bow or stress, as described in http://www.frontiersemi.com/center/products.php, which reference is incorporated by reference herein.

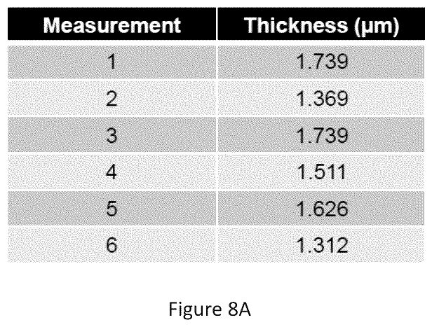

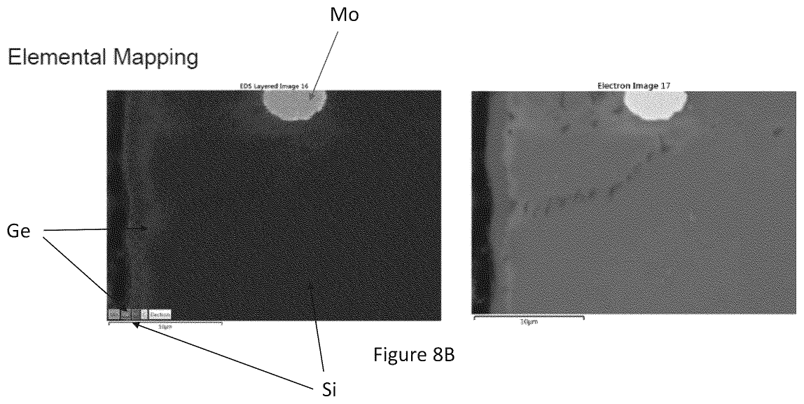

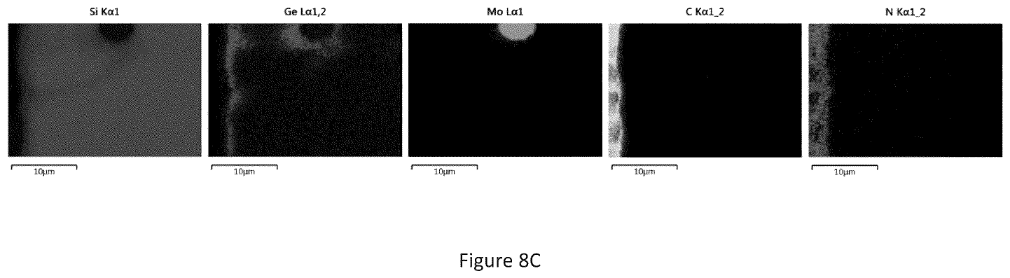

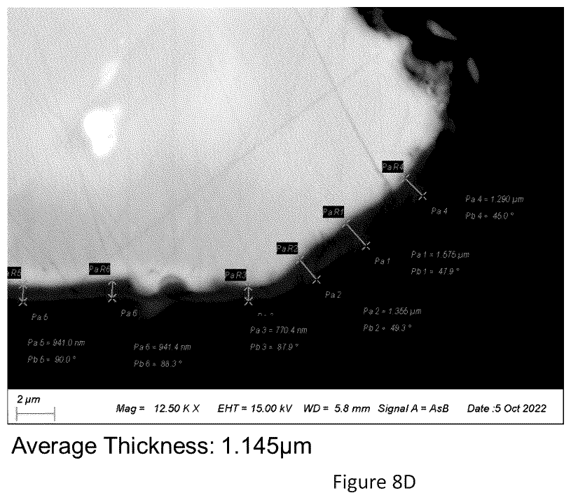

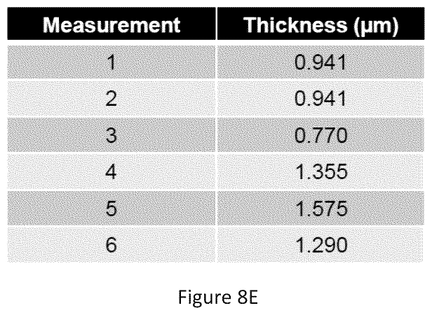

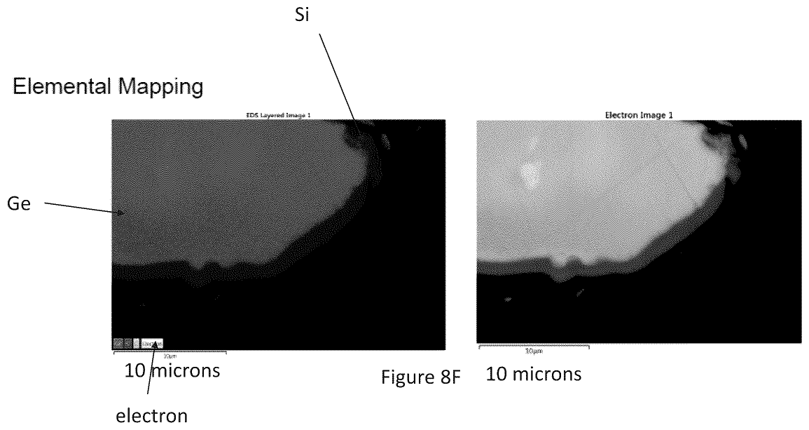

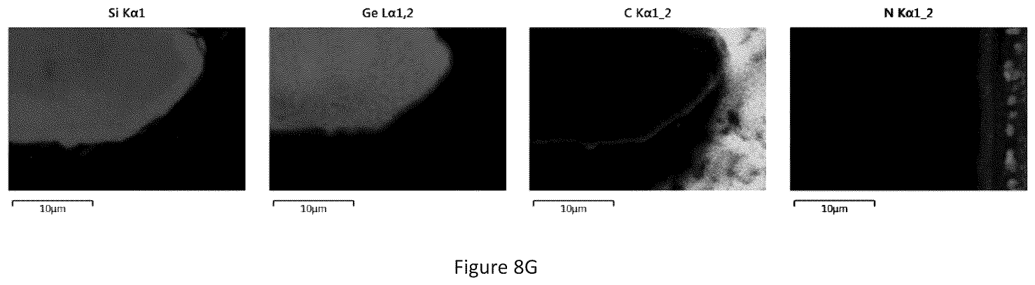

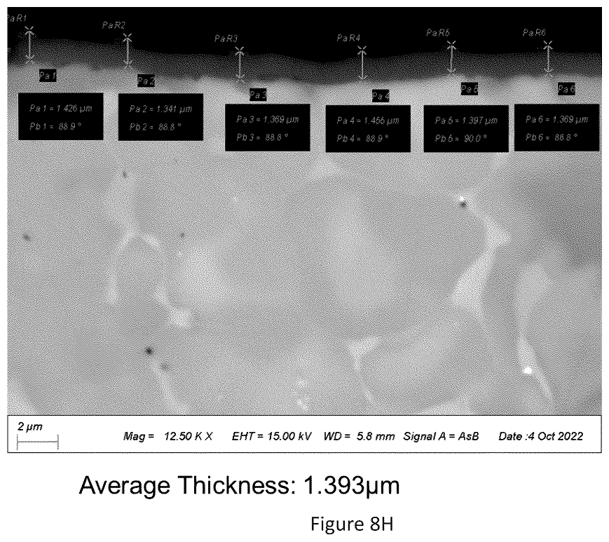

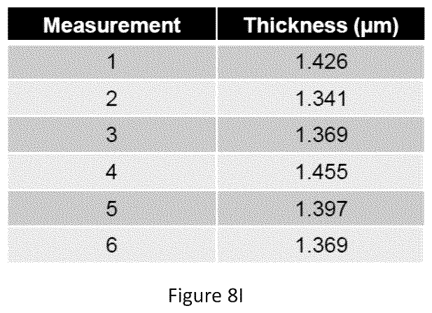

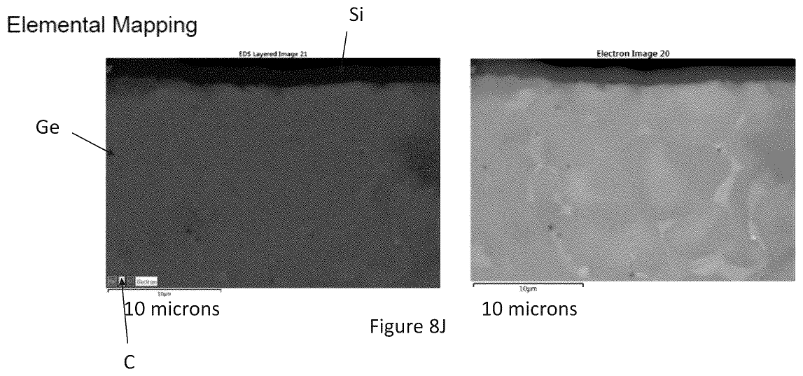

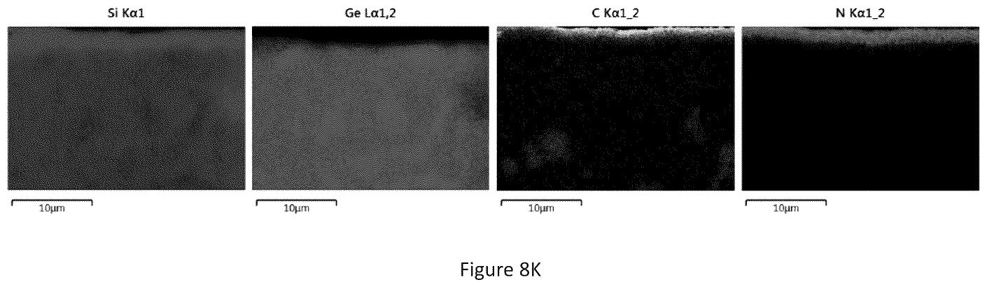

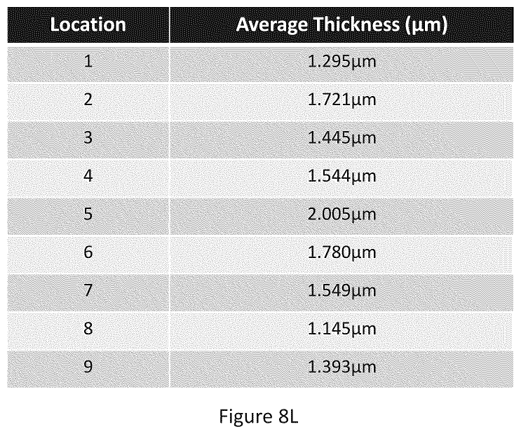

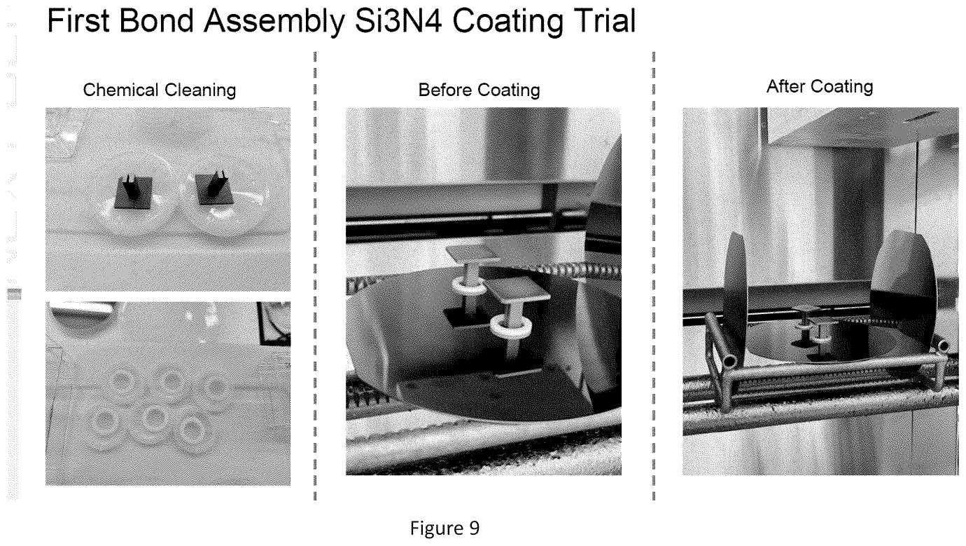

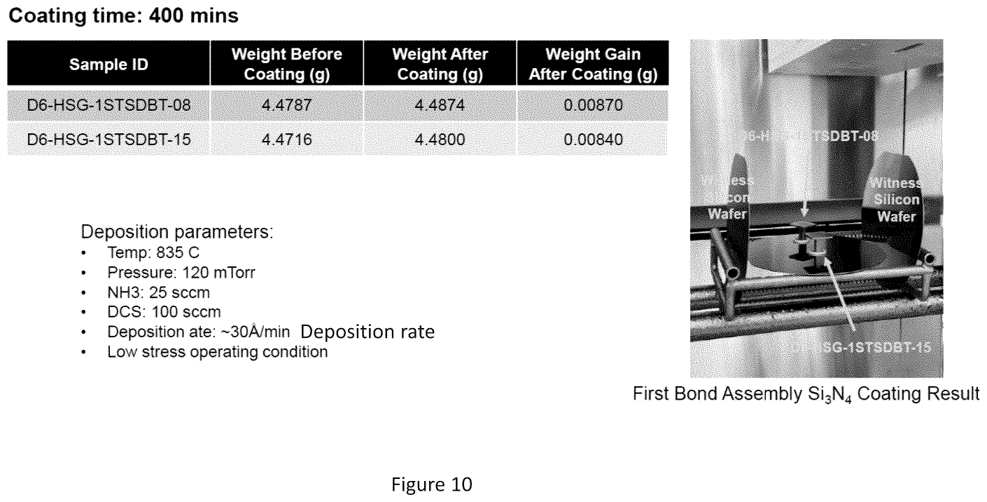

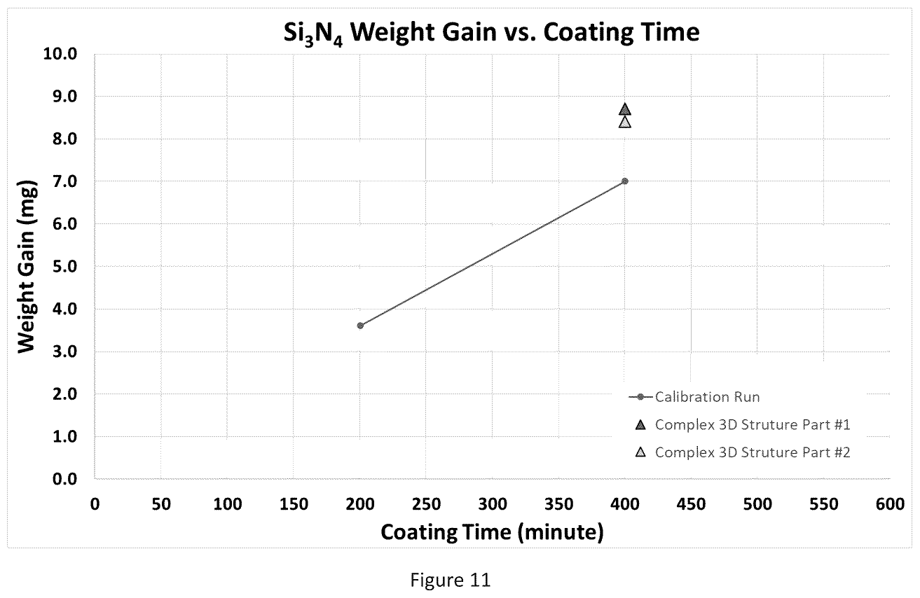

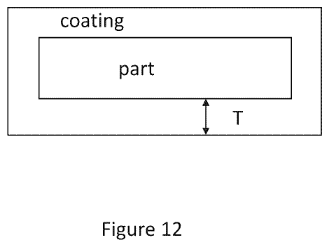

Although silicon nitride was deposited on SiGe in this example for a specific thickness range, a variety of oxides or doped oxides at different thicknesses can be deposited on different parts using the methods described herein, as described in the following clauses (referring also to FIGS. 1-11).
1. A part 700 on which the coating 706 is deposited can include three dimensional (3D) parts comprising or consisting of a semiconductor or a ceramic.
2. A part (including the part of clause 1) can comprise a coatings comprising or consisting essentially of at least one of silicon, an oxide of silicon, a nitride of silicon, an oxynitride of silicon, or a doped version thereof.
3. The part of any of the clauses 1-2 wherein the thicknesses T of the coating is in a range of 0.5 μm≤T≤10 μm, 1 μm≤T≤5 μm, 0.5 μm≤T≤5 μm.
4. The part of any of the clauses 1-3 wherein the coating can be on all regions/surface of the part, or only on some regions, e.g., with at least 90% coverage. In one or more examples using the RTG part, the base of the pedestals near the platform wafer is not covered.
5. The part of any of the clauses 1-4 wherein the part can be coated on all surfaces in one deposition run without flipping the part to expose the underside.
6. The part of any of the clauses 1-5 wherein the thickness of the coating is uniform across one or more of the surface to within 60% of the average thickness.
7. The part of any of the clauses 1-6, wherein the thickness variation is no more than a value equivalent to a variation of 600 Angstroms on a 1 micron thick coating, across a horizontal distance of 150 mm.
8. The part of any of the clauses 1-6, wherein the thickness variation of the coating is no more than a value equivalent to a standard deviation of 0.41 μm for an average thickness of 1.53 μm at all locations on a part that is smaller than 15 mm by 15 mm by 15 mm or at all locations on a part that fits on the boat for the LPCVD as described herein.
9. The part of any of the clauses 1-8 wherein the coating has a tensile stress S in a range of 50 MPa-150 MPa (e.g., 50 MPa≤S≤150 MPa) as measured using the technique of http://www.frontiersemi.com/center/products.php.
10. The part of any of the clauses 1-9, wherein the part comprises a semiconductor device (e.g., silicon related semiconductor device), a ceramic part (e.g., machined ceramic part), a battery component (e.g., electrode or housing), a 3D printed part comprising porous ceramic, wherein the coating renders the part more robust), a ceramic deformable mirror (e.g., comprising lead magnesium niobate ceramic block that can be actuated to deform the mirror), a printed circuit board, a trace, or dielectric layer, a thermoelectric module (e.g., one or more couples 700) that can be small scale or large, or any other device that uses the coating as a passivation layer (e.g., a thick robust passivation layer).
11. The part of any of the clauses 1-10 comprising a 3D object with a high aspect ratio and/or comprising an extended member, or a platform supported by one or more pedestals.
12. The part of any of the clauses 1-11, wherein a stoichiometry or other property of the coating can be tuned by controlling the output of the gas source.
13. The part of any of the clauses 1-12, wherein the composition (e.g., stoichiometric composition) is uniform across the part to within 1%.
14, The part of any of the clauses 1-13, wherein the coating comprises a film having properties (e.g., comprising mechanical properties, optical properties, electrical properties, and thickness and composition) characteristic of a film deposited by the LPCVD. The properties can be tailored for an application using the deposition conditions of the LPCVD,
15. The part of any of the clauses 1-14, wherein the coating comprises a film comprising SixNy, where x and y indicate the amounts of silicon and nitrogen, e.g. Si₃N₄.
16. The part of any of the clauses 1-15 comprising a thermoelectric module comprising a couple comprising a hot shoe (heat receptor), n-pellet or n-type thermoelectric alloy or material (e.g., n-type SiGe) and p-pellet or p-type thermoelectric alloy or material (e.g., p-type SiGe).
17. The part of any of the clauses 1-16 wherein the coating comprising a low stress (e.g., low tensile stress) film (thick or thin film).
18, The part of any of the clauses comprising a non-planar part or part different from a wafer, or any 3D object or 3D part.
19. An LPCVD reactor for depositing a part of any of the clauses and using the method of any of the clauses, further comprising a controller (e.g., comprising gas controller) for controlling deposition parameters such as gas precursor flows, deposition rate, temperature, and pressure. The controller may comprise a computer in one or more examples.

### Advantages and Improvements

As compared to Atmospheric Pressure Chemical Vapor deposition (at atmospheric pressure), LPCVD can provide increased purity, improved coating thickness uniformity and homogeneity, with more reproducible and reliable results.

### REFERENCES

The following references are incorporated by reference herein.
[1] Ivanda, M., et al. “Low pressure chemical vapor deposition of different Silicon nanostructures.” International Journal of Thermophysics 57 (2009): 1-5
[2] http://www.frontiersemi.com/center/products.php.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
configuring a boat to hold one or more three-dimensional (3D) structures, wherein a platform wafer is placed horizontally in the boat to support the complex 3D structures;
loading the boat, the 3D structures, and the platform wafer, into a chemical vapor deposition (CVD) furnace;
performing a coating of the 3D structures supported on the platform wafer in the CVD furnace; and
unloading the 3D structures from the CVD furnace after the coating is performed.

2. The method of claim 1, wherein the boat comprises a first slot and a second slot and the configuring comprises placing a first wafer vertically in the first slot; placing a second wafer vertically in the second slot; and placing the platform wafer horizontally between the first wafer and the second wafer.

3. The method of claim 1, further comprising placing the 3D structures on the platform wafer using one or more rings to keep the 3D structures from moving after being placed on the on the platform wafer.

4. The method of claim 1, wherein the coating is a silicon nitride coating.

5. The method of claim 1, wherein the CVD furnace is a CVD furnace intended to only coat wafers.

6. The method of claim 1, wherein the CVD furnace is a low-pressure CVD furnace and the coating is performed at a pressure in a range of 10 mTorr to 1 Torr.

7. The method of claim 1, further comprising analyzing the coating on at least one of the 3D structures or one or more witness wafers loaded into the boat with the 3D structures.

8. One or more three-dimensional (3D) structures coated by the method of claim 1.

9. The structures of claim 8 comprising consisting essentially of silicon and germanium and the coating.

10. The structures of claim 8, comprising a platform connected to columns extending from the platform.

11. The structures of claim 8, comprising a component of a radioisotope thermoelectric generator (RTGs).

12. An apparatus, comprising:
a boat, comprising:
a horizontal platform; and
a mount for securely for holding a three dimensional part other than a wafer on the platform during a low pressure chemical vapor deposition process.

13. The apparatus of claim 12, wherein the mount comprises fixture fixing the part on a top surface of the horizontal platform.

14. The apparatus of claim 14, further comprising a first vertical sidewall and a second vertical sidewall wherein the platform is between the sidewalls.

15. The apparatus of claim 14, wherein the sidewalls comprise witness waters used to characterize a coating deposited using the chemical vapor deposition process.

16. An article of manufacture or part, comprising:
a three dimensional part different from a wafer and comprising a top surface; a bottom surface; and vertical sidewalk; and
a coating on each of the surfaces characterized by being deposited by low pressure chemical vapor deposition.

17. The article of manufacture of claim 16, wherein:
the 3D part comprises or consists essentially of a semiconductor or a ceramic; and
the coating comprises or consists essentially of at least one of silicon, an oxide of silicon, a nitride of silicon, an oxynitride of silicon, or a doped version thereof;
the coating has at least one of:
a uniform thickness across one or more of the surface to within 60% of the average thickness, or
the coating has a tensile stress in a range of 50 MPa-150 MPa.

18. The article of manufacture of claim 16, wherein the part comprises a radioisotope thermoelectric generator (RTGs), a ceramic part; one or more couples in a thermoelectric module; a 3D printed part, a porous 3D printed part; a battery component; a mirror; or a semiconductor device.

19. The article of manufacture of claim 16 wherein the part comprises a thermoelectric couple.
